(19) United States
(12) Patent Application Publication
(10) Pub. No.: US 2016/0307799 A1
(43) Pub. Date: Oct. 20, 2016

(54) SEMICONDUCTOR SUBSTRATES, SEMICONDUCTOR PACKAGES AND PROCESSES OF MAKING THE SAME

(71) Applicant: Advanced Semiconductor Engineering, Inc., Kaohsiung (TW)

(72) Inventors: Sheng-Chun HO, Kaohsiung (TW); Che-Yuan CHANG, Kaohsiung (TW); Chung-Shou WU, Kaohsiung (TW); Chi-Hsin LIN, Kaohsiung (TW)

(73) Assignee: Advanced Semiconductor Engineering, Inc.

(21) Appl. No.: 14/687,851

(22) Filed: Apr. 15, 2015

(51) Int. Cl. H01L 21/768; H01L 21/324; H01L 23/535; H01L 21/304; B41J 2/01; H01L 23/29

(52) U.S. Cl. CPC H01L 21/76885; B41J 2/01; H01L 23/293; H01L 23/535; H01L 21/304; H01L 21/324; H01L 21/76834; H01L 21/76805

(57) ABSTRACT

The present disclosure relates to semiconductor substrates useful in semiconductor packages. In an embodiment, a semiconductor substrate comprises a patterned conductive layer, a patterned insulating layer, and a first protection layer. The patterned conductive layer has a first surface and a second surface opposite the first surface, and defines at least one space. The patterned insulating layer is disposed in the space, and has a third surface and a fourth surface opposite the third surface, where the third surface of the patterned insulating layer does not protrude from the first surface of the patterned conductive layer, and the patterned insulating layer comprises, or is formed from, a cured photo-sensitive resin. The first protection layer covers at least a portion of the second surface of the patterned conductive layer.

### BACKGROUND

1. Technical Field

The present disclosure relates to semiconductor packages and semiconductor processes, and, in particular, to semiconductor packages including a semiconductor substrate and processes of making the same.

2. Description of the Related Art

In a semiconductor packaging process, a semiconductor chip or die is typically mounted and electrically connected to a substrate to increase the number of external connection terminals for the chip. The semiconductor chip may be a flip-chip type or a wire-bond type. Conductive patterns, such as traces and connection pads, are typically provided on the substrate to electrically connect the semiconductor chip to the substrate and further provide the semiconductor chip with external connections.

Traces and connection pads on a substrate should be insulated from one another to avoid undesired short circuits between such structures. Nevertheless, due to the trend of miniaturization, it would be a challenge to fill a small space between the traces and connection pads with encapsulant materials. Failure of filling encapsulant materials into the space between traces and pads or between a trace and an interconnecting element, such as a solder ball that connects a semiconductor chip to the substrate, may result in voids in a resulting semiconductor package. Moreover, failure of controlling the volume or size of the interconnecting element during the packaging process may cause a short circuit in the semiconductor package. Therefore, it is desirable to provide a semiconductor package having an improved semiconductor substrate and an improved process of making the same to solve the aforesaid problems.

### SUMMARY

One aspect of the present disclosure relates to a semiconductor substrate. In an embodiment, the semiconductor substrate comprises a patterned conductive layer, a patterned insulating layer, and a first protection layer. The patterned conductive layer has a first surface and a second surface opposite the first surface, where the patterned conductive layer defines at least one space. The patterned insulating layer is disposed in the space, and has a third surface and a fourth surface opposite the third surface, where the third surface of the patterned insulating layer does not protrude from the first surface of the patterned conductive layer, and the patterned insulating layer comprises, or is formed from, a cured photo-sensitive resin. The first protection layer covers at least a portion of the second surface of the patterned conductive layer.

Another aspect of the present disclosure relates to a semiconductor package. In an embodiment, the semiconductor package comprises a semiconductor substrate, a die, and an encapsulant. The semiconductor substrate comprises the components as described above. The die is disposed on the first surface of the patterned conductive layer, and the encapsulant covers the die and the semiconductor substrate.

Another aspect of the present disclosure relates to a semiconductor process. In an embodiment, the semiconductor process comprises: (1) providing a carrier; (2) forming a patterned conductive layer on the carrier, where the patterned conductive layer defines at least one space; (3) forming a photo-sensitive resin layer on the patterned conductive layer, where the photo-sensitive resin layer covers the patterned conductive layer and fills the space; and (4) removing a top portion of the photo-sensitive resin layer to expose a top surface of the patterned conductive layer and such that a top surface of the photo-sensitive resin layer does not protrude from the top surface of the patterned conductive layer.

Another aspect of the present disclosure relates to a semiconductor process. In an embodiment, the semiconductor process comprises: (1) providing a semiconductor substrate disposed on a carrier, the semiconductor substrate comprising: (a) a patterned conductive layer disposed on the carrier, where the patterned conductive layer has a first surface and a second surface opposite the first surface, and defines at least one space; and (b) a patterned insulating layer disposed in the space and having a third surface and a fourth surface opposite the third surface, where the third surface of the patterned insulating layer does not protrude from the first surface of the patterned conductive layer, and the patterned insulating layer comprises, or is formed from, a cured photo-sensitive resin; (2) electrically connecting a die to the first surface of the patterned conductive layer; (3) encapsulating the die and the semiconductor substrate; and (4) removing the carrier.

### BRIEF DESCRIPTION OF THE DRAWINGS

FIG. 1 illustrates a cross-sectional view of a semiconductor substrate according to an embodiment of the present disclosure.

FIG. 2 illustrates a cross-sectional view of a semiconductor substrate according to another embodiment of the present disclosure.

FIG. 3 illustrates a cross-sectional view of a semiconductor substrate according to another embodiment of the present disclosure.

FIG. 4 illustrates a cross-sectional view of a semiconductor substrate according to another embodiment of the present disclosure.

FIG. 5 illustrates a cross-sectional view of a semiconductor package according to an embodiment of the present disclosure.

FIG. 6 illustrates a cross-sectional view of a semiconductor package according to another embodiment of the present disclosure.

FIG. 7A, FIG. 7B, FIG. 7C, FIG. 7D, FIG. 7E, FIG. 7F, FIG. 7G(a), FIG. 7G(b), FIG. 7H, FIG. 7I, FIG. 7J, FIG. 7K, and FIG. 7L illustrate a process of manufacturing a semiconductor package according to an embodiment of the present disclosure.

FIG. 8A, FIG. 8B, FIG. 8C, FIG. 8D, FIG. 8E, FIG. 8F, FIG. 8G, FIG. 8H, FIG. 8I, FIG. 8J, FIG. 8K, FIG. 8L, FIG. 8M, FIG. 8N, FIG. 8O, and FIG. 8P illustrate a process of manufacturing a semiconductor package according to another embodiment of the present disclosure.

### DETAILED DESCRIPTION

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are specified with respect to a certain element or certain plane of an element, as described in the specification and shown in the figures. Furthermore, it should be understood that the spatial descriptions used herein are for purposes of illustration only, and that practical implementations of the structures described herein can be spatially arranged in any orientation or manner, provided that the merits of embodiments of this disclosure are not deviated by such arrangement.

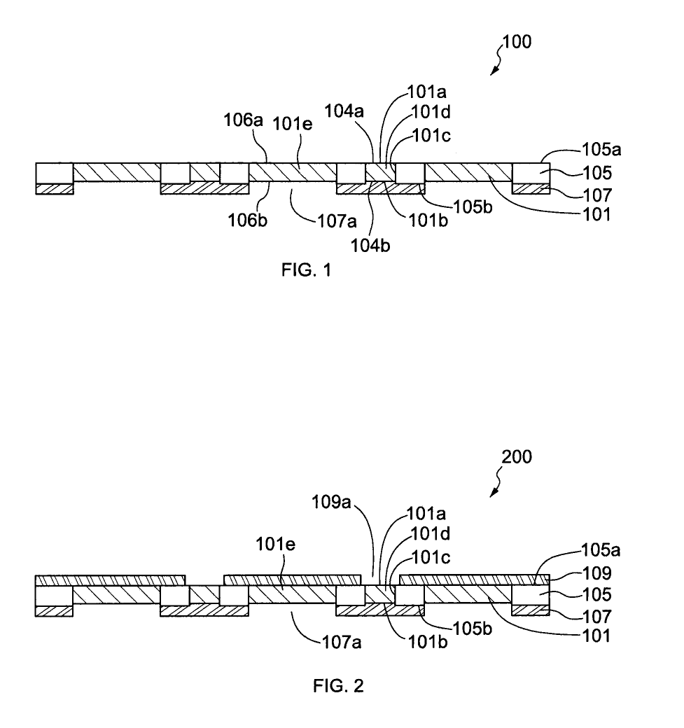

FIG. 1 illustrates a cross-sectional view of a semiconductor substrate 100 according to an embodiment of the present disclosure. The semiconductor substrate 100 comprises a patterned conductive layer 101, a patterned insulating layer 105 including, or formed from, a cured photo-sensitive resin, and a first protection layer 107.

The patterned conductive layer 101 has a first surface 101a and a second surface 101b. The first surface 101a is opposite the second surface 101b. The patterned conductive layer 101 comprises a plurality of traces and connection pads, such as ball pads and bonding pads. In this embodiment, a first portion 101d of the patterned conductive layer 101 and a second portion 101e of the patterned conductive layer 101 are bonding pads and ball pads, respectively. A first surface 104a of the bonding pad 101d may be substantially coplanar with a first surface 106a of the ball pad 101e. A second surface 104b of the bonding pad 101d may be substantially coplanar with a second surface 106b of the ball pad 101e. The material of the bonding pad 101d and the material of the ball pad 101e may be the same or different, and may be independently selected from, for example, one of, or a combination of, copper, gold, indium, tin, silver, palladium, osmium, iridium, ruthenium, titanium, magnesium, aluminum, cobalt, nickel, zinc, and other metals or metal alloys. The patterned conductive layer 101 has at least one space 101c formed between the traces and connection pads. The space 101c may be a hole or an opening. The patterned conductive layer has a thickness of about 14 μm to about 26 μm, such as about 14 μm to about 20 μm or about 20 μm to about 26 μm.

The patterned insulating layer 105 is disposed or filled in the space 101c. The patterned insulating layer 105 has a third surface 105a and a fourth surface 105b opposite the third surface 105a. In this embodiment, the third surface 105a does not protrude from, or does not extend vertically above, the first surface 101a of the patterned conductive layer 101. That is, the third surface 105a may be coplanar or substantially coplanar with or may be recessed below the first surface 101a of the patterned conductive layer 101. In this embodiment, the third surface 105a is substantially coplanar with the first surface 101a of the patterned conductive layer 101. In this embodiment, the fourth surface 105b of the patterned insulating layer 105 protrudes from, or extends vertically below, the second surface 101b of the patterned conductive layer 101. That is, the second surface 101b of the patterned conductive layer 101 is recessed above the fourth surface 105b of the patterned insulating layer 105.

The patterned insulating layer 105 comprises, or is formed from, at least one resin having at least one moiety that may polymerize upon being irradiated with electromagnetic radiation, such as ultraviolet (UV) light, or at least one curing resin that lowers its curing temperature upon being irradiated with electromagnetic radiation. Any resin that satisfies the purposes mentioned above may be used, and which may be used either individually or as a combination of two or more such resins. For example, a suitable photo-sensitive resin may comprise at least one resin selected from the group consisting of acrylic polymers and acrylic copolymers. The photo-sensitive resin may also comprise at least one resin having at least one moiety selected from the group consisting of an epoxy group, an imide bond, an ether bond, an ester bond, an urethane bond, and an amide bond. Other components may be included along with the photo-sensitive resin, such as, for example, one of, or a combination of, at least one photo-initiator, at least one additive, at least one inorganic compound (such as a filler), at least one colorant, at least one epoxy curing agent, at least one chain transfer agent, at least one sensitizer, and at least one solvent.

The first protection layer 107 is disposed adjacent to the second surface 101b of the patterned conductive layer 101 and also the fourth surface 105b of the patterned insulating layer 105. In this embodiment, the first protection layer 107 covers at least a portion of the second surface 101b of the patterned conductive layer and at least a portion of the fourth surface 105b of the patterned insulating layer 105. The first protection layer 107 has at least one opening 107a to expose a portion of the second surface 101b of the patterned conductive layer 101, such as corresponding to the ball pad 101e. Such opening 107a serves to provide an external electrical connection, such as an external electrical connection to a semiconductor element (such as a printed circuit board). The first protection layer 107 may be an organic insulating layer, the material of which is, for example, polyimide (PI). The material of the first protection layer 107 and the material of the patterned insulating layer 105 may be the same or different. If the material of the first protection layer 107 and the material of the patterned insulating layer 105 are the same, there may not be a distinct boundary at the interface between the first protection layer 107 and the patterned insulating layer 105.

In this embodiment, a photo-sensitive resin, rather than a C-stage thermosetting resin, is disposed in the space 101c between the traces and connection pads to form the patterned insulating layer 105. Accordingly, a time duration to perform a grinding process on the photo-sensitive resin, which initially covers the patterned conductive layer 101, in order to expose the bonding pads 101d can be reduced because the photo-sensitive resin is ground at a B-stage. A C-stage thermosetting resin after thermal curing has a relatively greater hardness than a B-stage resin; thus, a relatively longer grinding process is involved in order to remove the thermosetting resin to expose the bonding pads underneath. In addition, such grinding often results in an over-grounded trace on a substrate, which can adversely affect the electrical performance of a resulting semiconductor package.

FIG. 2 illustrates a cross-sectional view of a semiconductor substrate 200 according to another embodiment of the present disclosure. The semiconductor substrate 200 of this embodiment is similar to the semiconductor substrate 100 as described and illustrated with reference to FIG. 1, except that a second protection layer 109 is disposed adjacent to the first surface 101a of the patterned conductive layer 101 and the third surface 105a of the patterned insulating layer 105. In this embodiment, the second protection layer 109 covers at least a portion of the first surface 101a of the patterned conductive layer 101 and at least a portion of the third surface 105a of the patterned insulating layer 105. The second protection layer 109 has at least one opening 109a to expose a portion of the first surface 101a of the patterned conductive layer 101 and a portion of the third surface 105a of the patterned insulating layer 105. In this embodiment, the opening 109a exposes at least a portion of the bonding pad 101d. Such opening 109a serves to provide an electrical connection to a semiconductor element (such as a die). The second protection layer 109 may be an organic insulating layer, the material of which is, for example, polyimide (PI). The material of the second protection layer 109 and the material of the patterned insulating layer 105 may be the same or different. If the material of the second protection layer 109 and the material of the patterned insulating layer 105 are the same, there may not be a distinct boundary at the interface between the second protection layer 109 and the patterned insulating layer 105.

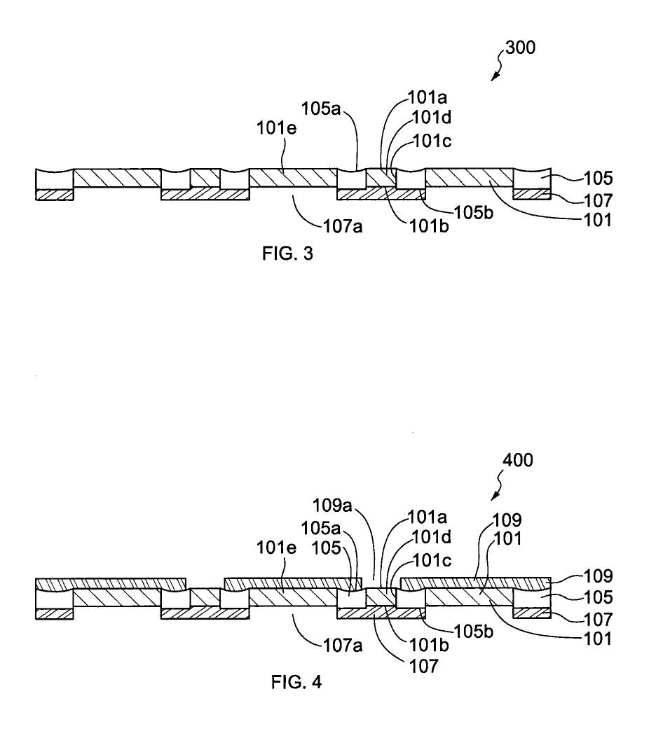

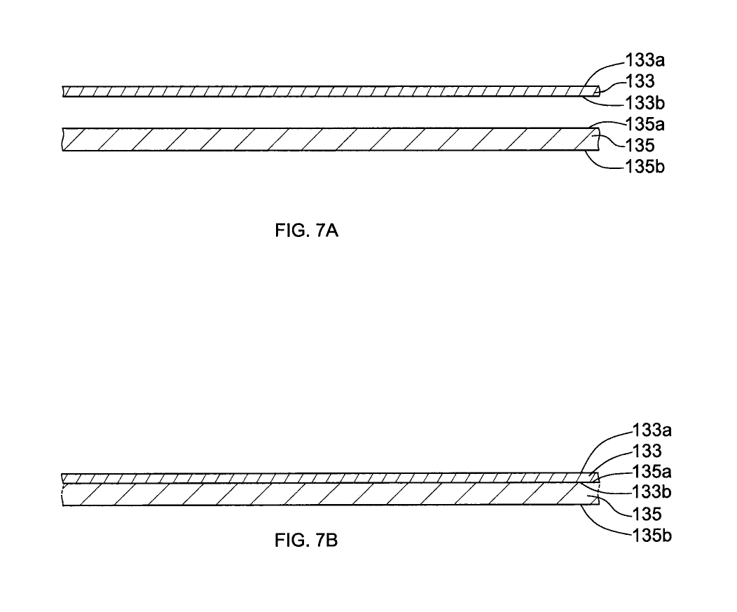

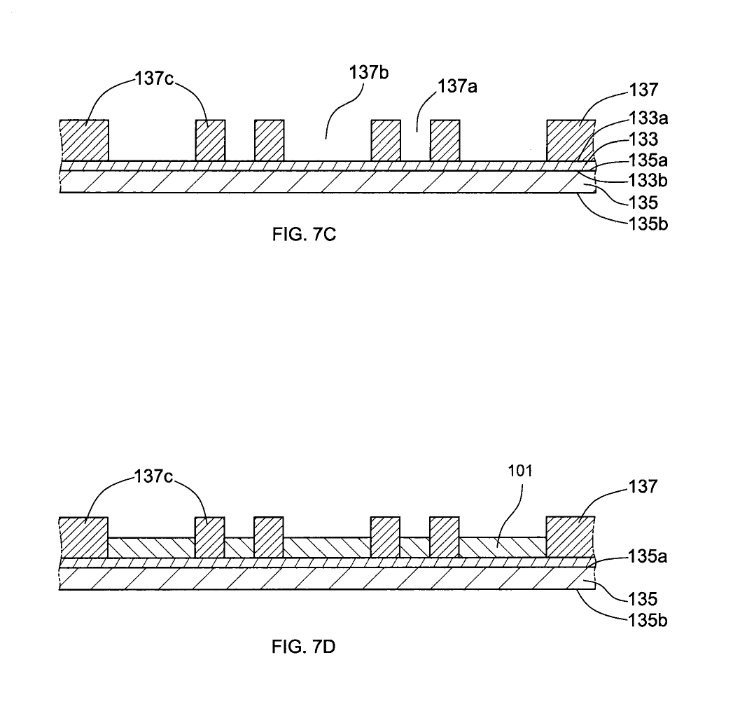

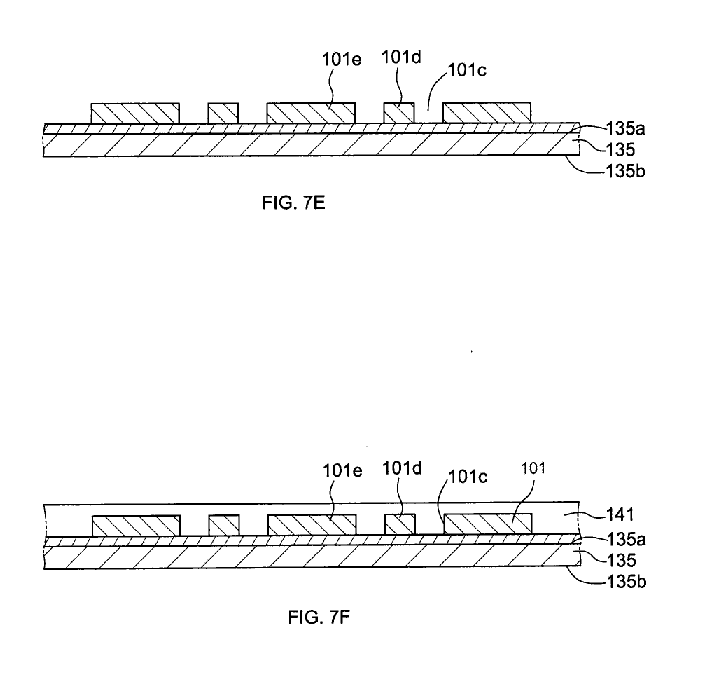

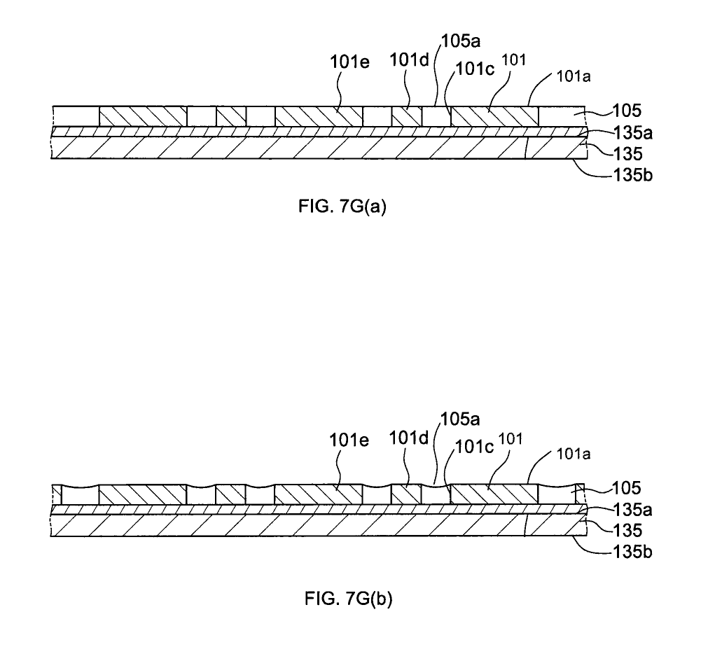

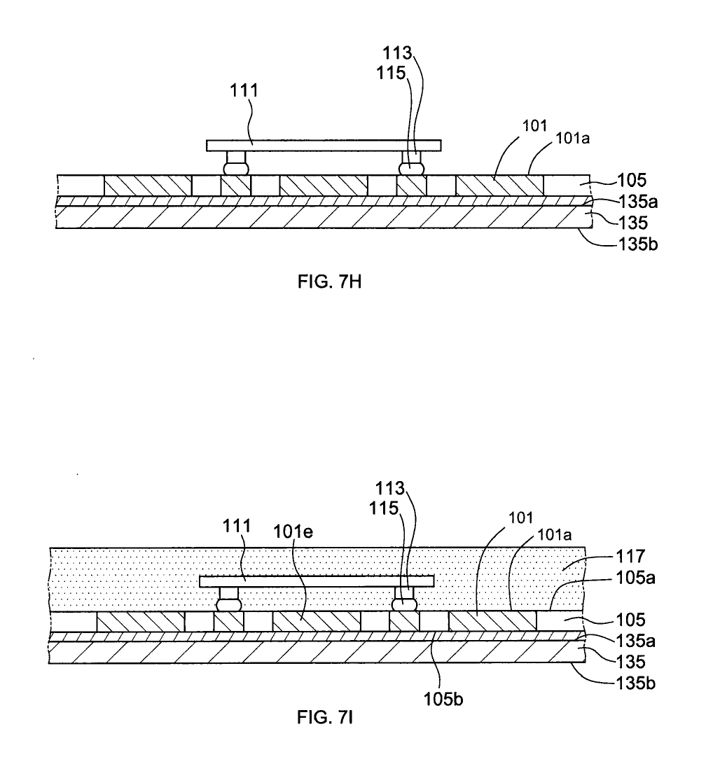

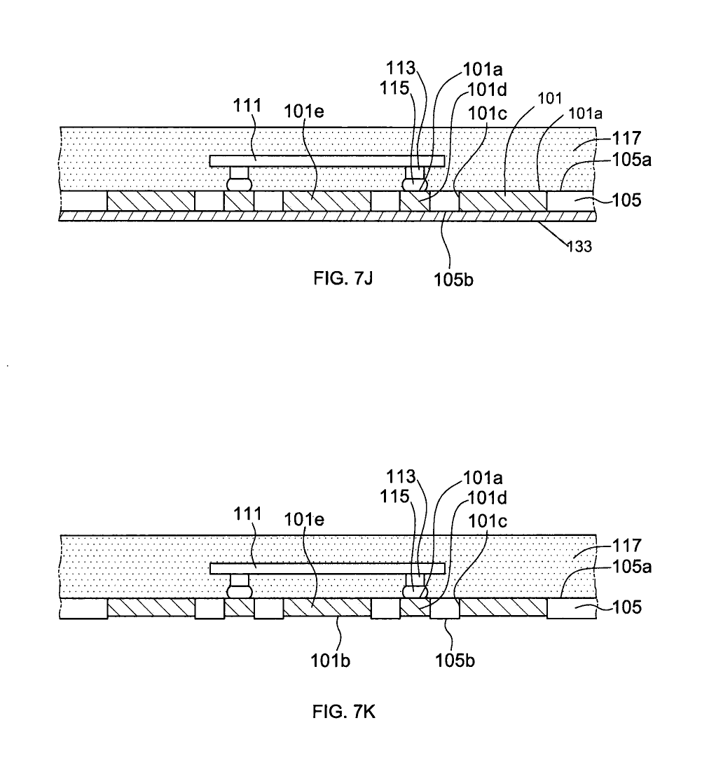

FIG. 3 illustrates a cross-sectional view of a semiconductor substrate 300 according to another embodiment of the present disclosure. The semiconductor substrate 300 of this embodiment is similar to the semiconductor substrate 100 as described and illustrated with reference to FIG. 1, except that at least a portion of the third surface 105a of the patterned insulating layer 105 is recessed below the first surface 101a of the patterned conductive layer 101. In this embodiment, the third surface 105a of the patterned insulating layer 105 has a curved or concave vertical profile, and the third surface 105a of the patterned insulating layer 105 and the first surface 101a of the patterned conductive layer 101 can be separated by a gap of about 3 μm to about 7 μm, such as about 3 μm to about 5 μm or about 5 μm to about 7 μm, with respect to a lowermost point of the third surface 105a of the patterned insulating layer 105. An example of formation of a recessed portion is described with respect to FIG. 7G(b).

FIG. 4 illustrates a cross-sectional view of a semiconductor substrate 400 according to another embodiment of the present disclosure. The semiconductor substrate 400 of this embodiment is similar to the semiconductor substrate 200 as described and illustrated with reference to FIG. 2, except that at least a portion of the third surface 105a of the patterned insulating layer 105 is recessed below the first surface 101a of the patterned conductive layer 101. As such, a portion of the second protection layer 109 is disposed in the recess of the patterned insulating layer 105, and such portion of the second protection layer 109 would be recessed below the first surface 101a of the patterned conductive layer 101.

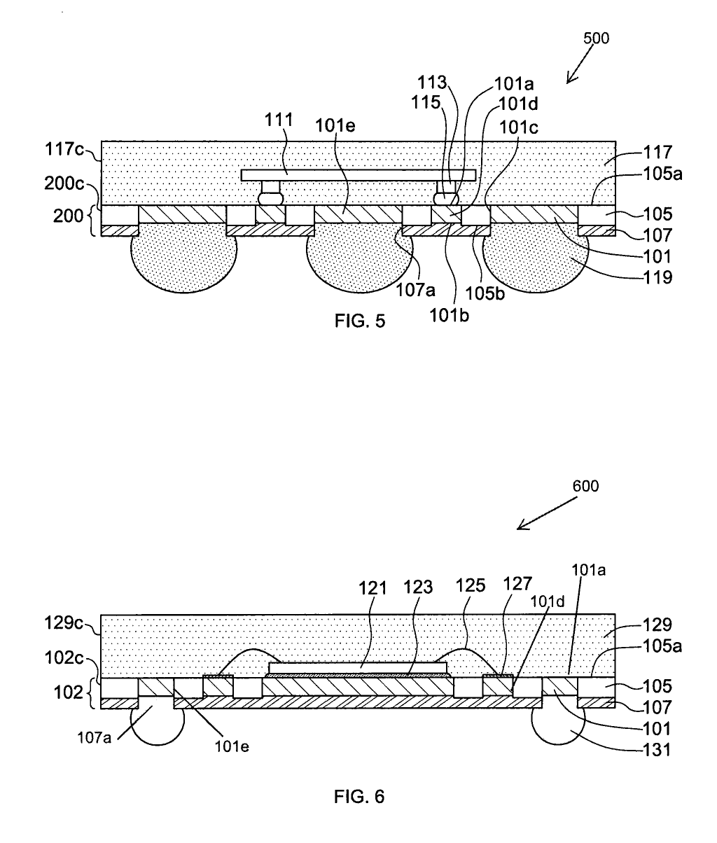

FIG. 5 illustrates a cross-sectional view of a semiconductor package 500 according to an embodiment of the present disclosure. The semiconductor package 500 comprises a semiconductor substrate 200, a semiconductor element 111 (for example, a semiconductor chip or die), at least one interconnecting element 113 (for example, a plurality of metal pillars) and a corresponding solder layer 115, an encapsulant 117, and a plurality of solder balls 119. The patterned conductive layer 101, the patterned insulating layer 105, and the first protection layer 107 of the semiconductor substrate 200 of this embodiment are similarly configured as the patterned conductive layer 101, the patterned insulating layer 105, and the first protection layer 107 of the semiconductor substrate 100 illustrated in FIG. 1, respectively.

The semiconductor element 111 is mounted and electrically connected to the semiconductor substrate 200. In this embodiment, the semiconductor element 111 is electrically connected to the first surface 101a of the patterned conductive layer 101 through the interconnecting element 113 and the solder layer 115. In another embodiment, the semiconductor package 500 can further include a second protection layer disposed on a periphery of a top surface of the semiconductor substrate 200 and having an opening to expose the patterned conductive layer 101 and patterned insulating layer 105 below the semiconductor element 111. That is, a projection area of the semiconductor element 111 on the semiconductor substrate 200 can be devoid of the second protection layer.

The interconnecting elements 113 are positioned on respective bonding pads 101d of the patterned conductive layer 101 of the semiconductor substrate 200 and respective pads of the semiconductor element 111 so as to connect the semiconductor element 111 to the semiconductor substrate 200. The interconnecting elements 113 can be, for example, solder/stud bumps or copper pillars. If the interconnecting elements 113 are solder bumps, the solder layer 115 may be omitted.

The encapsulant 117 covers at least a portion of the semiconductor element 111 and surrounds the interconnecting element 113 and the solder layer 115. In this embodiment, a side surface 117c of the encapsulant 117 is coplanar or substantially coplanar with a side surface 200c of the semiconductor substrate 200. However, in another embodiment, the encapsulant 117 may further cover the side surface 200c of the semiconductor substrate 200. A material of the encapsulant 117 can include, for example, an epoxy resin or a molding compound.

The solder balls 119 serve as external connection terminals. The solder balls 119 attach to respective ball pads 101e of the patterned conductive layer 101 through respective openings 107a of the first protection layer 107 of the semiconductor substrate 200. That is, a portion of each solder ball 119 is disposed in a respective opening 107a.

FIG. 6 illustrates a cross-sectional view of a semiconductor package 600 according to another embodiment of the present disclosure. The semiconductor package 600 comprises a semiconductor substrate 102, a semiconductor element 121, an adhesive 123, a plurality of bonding wires 125, a plurality of bonding pads 127, an encapsulant 129, and a plurality of solder balls 131. The patterned conductive layer 101, the patterned insulating layer 105, and the first protection layer 107 of the semiconductor substrate 102 of this embodiment are similarly configured as the patterned conductive layer 101, the patterned insulating layer 105, and the first protection layer 107 of the semiconductor substrate 100 illustrated in FIG. 1, respectively.

The semiconductor element 121 is electrically connected to the semiconductor substrate 102. The semiconductor element 121 is disposed adjacent to the first surface 101a of the patterned conductive layer 101 of the semiconductor substrate 102. In this embodiment, the semiconductor element 121 is disposed on the first surface 101a of the patterned conductive layer 101 through the adhesive 123 and is electrically connected to the first surface 101a of the patterned conductive layer 101 through the bonding wires 125 and the bonding pads 127.

The bonding pads 127 are positioned on respective bonding pads 101d of the patterned conductive layer 101 of the semiconductor substrate 102 so as to connect to the semiconductor element 121 through the bonding wires 125.

The encapsulant 129 covers at least a portion of the semiconductor element 121, at least a portion of the bonding wires 125, and at least a portion of the adhesive 123. In this embodiment, a side surface 129c of the encapsulant 129 is coplanar or substantially coplanar with a side surface 102c of the semiconductor substrate 102. However, in another embodiment, the encapsulant 129 may further cover the side surface 102c of the semiconductor substrate 102. A material of the encapsulant 129 can include, for example, an epoxy resin or a molding compound.

The solder balls 131 serve as external connection terminals. The solder balls 131 attach to respective ball pads 101e of the patterned conductive layer 101 through respective openings 107a of the first protection layer 107 of the semiconductor substrate 102. That is, a portion of each solder ball 131 is disposed in a respective opening 107a.

FIG. 7A, FIG. 7B, FIG. 7C, FIG. 7D, FIG. 7E, FIG. 7F, FIG. 7G(a), FIG. 7G(b), FIG. 7H, FIG. 7I, FIG. 7J, FIG. 7K, and FIG. 7L illustrate a process of manufacturing a semiconductor package according to an embodiment of the present disclosure.

Referring to FIG. 7A, a carrier 135 and a metal foil 133 are provided. The carrier 135 has a first surface 135a and a second surface 135b. The first surface 135a is opposite the second surface 135b. The metal foil has a third surface 133a and a fourth surface 133b. The third surface 133a is opposite the fourth surface 133b. The material of the metal foil 133 may comprise copper or other suitable materials, such as other metals or metal alloys. In this embodiment, the metal foil 133 is a copper foil.

Referring to FIG. 7B, the metal foil 133 is disposed on the first surface 135a of the carrier 135 by its fourth surface 133b. The metal foil 133 can be disposed on the first surface 135a of the carrier 135 by any suitable manner. In this embodiment, the metal foil 133 is disposed on the first surface 135a of the carrier 135 by lamination.

Referring to FIG. 7C, a patterned mask layer 137 is disposed on the third surface 133a of the metal foil 133. A mask layer is patterned to form the patterned mask layer 137 that defines the spaces 137a, 137b to expose a portion of the metal foil 133, where the location of the first space 137a of the patterned mask layer 137 corresponds to an area to form the bonding pad 101d, and the location of the second space 137b corresponds to an area to form the ball pad 101e. The mask layer may be, for example, a dry film.

Referring to FIG. 7D, a conductive material is disposed within the spaces 137a, 137b defined by the patterned mask layer 137 to form the patterned conductive layer 101. In this embodiment, the conductive material may be formed by electroplating or electroless plating. The material of the patterned conductive layer 101 and the material of the metal foil 133 may be the same or different. In this embodiment, the material of the patterned conductive layer 101 and the material of the metal foil 133 both comprise copper.

Referring to FIG. 7E, the patterned mask layer 137 is removed, and the patterned conductive layer 101 is formed.

Referring to FIG. 7F, an insulating material is disposed on the patterned conductive layer 101 to form a photo-sensitive resin layer 141. The photo-sensitive resin layer 141 fills the space 101c and covers a top surface of the patterned conductive layer 101. In this embodiment, the insulating material comprises an acrylic resin and a photo-initiator that may polymerize upon being irradiated with electromagnetic radiation. The insulating material is half-cured or partially cured by irradiation to have a hardness (e.g., according to the pencil hardness test) of HB to 2B or to a B-stage.

Referring to FIG. 7G(a), a top portion of the photo-sensitive resin layer 141 is removed to expose the first surface 101a of the patterned conductive layer 101 for die bonding and to form the patterned insulating layer 105. In this embodiment, the portion of the photo-sensitive resin layer 141 is removed in a manner such that the third surface 105a of the patterned insulating layer 105 does not protrude from the first surface 101a of the patterned conductive layer 101 to expose the first surface 101a of the patterned conductive layer 101 for die bonding. Referring to FIG. 7G(b), in another embodiment, the portion of the photo-sensitive resin layer 141 is removed in a manner such that the third surface 105a of the patterned insulating layer 105 is recessed below the first surface 101a of the patterned conductive layer 101 to expose the first surface 101a of the patterned conductive layer 101 for die bonding. The removal can be accomplished by a grinding technique, for example. Since the photo-sensitive resin layer 141 is in a B-stage or has a hardness of HB to 2B when it is grounded, which is softer compared to a fully cured resin, the grinding process can be controlled more easily and precisely. As a result, over-grinding of the patterned conductive layer 101 can avoided, and the patterned conductive layer 101 can be maintained at an acceptable thickness. The following table shows a comparison between copper grinding loss according to an embodiment of the present disclosure, which employs a photo-sensitive resin and another embodiment of the present disclosure, which employs a C-stage thermoset resin.

| | An | Another |
|---|---|---|
| | embodiment | embodiment |
| | of the | of the |
| | present | present |
| | disclosure | disclosure |
| Copper Grinding Loss | about 5 μm | about 8 μm |
| The trace thickness | about 15 μm | about 12 μm |
| after grinding | | |

As seen from the table, the copper grinding loss for the half-cured photo-sensitive resin layer 141 according to an embodiment of the present disclosure can allow the patterned conductive layer 101 to be within an acceptable thickness, for example a thickness of 20±6 μm. On the other hand, the copper grinding loss for a thermoset resin will result in a patterned conductive layer that is too thin (outside the range of thickness of 20±6 μm). In addition, since the photo-sensitive resin layer 141 is disposed on the patterned conductive layer 101 in a fluid state, the photo-sensitive resin layer 141 can fill the space 101c more readily and more completely, and can cover the top surface of the patterned conductive layer 101 in a more uniform manner.

Next, a thermal or other curing process can be carried out such that the patterned insulating layer 105 after removal is in a fully or substantially fully cured state.

Referring to FIG. 7H, the semiconductor element 111 is mounted and electrically connected to the first surface 101a of the patterned conductive layer 101 through the interconnecting elements 113 and the solder layer 115.

Referring to FIG. 7I, the encapsulant 117 (e.g., a molding compound) is disposed on the patterned conductive layer 101 and the patterned insulating layer 105. The encapsulant 117 covers the semiconductor element 111 and surrounds the interconnecting elements 113 and the solder layer 115. The carrier 135 may enhance the rigidity of the substrate at the time of die bonding and encapsulating, especially when the substrate includes the patterned conductive layer 101 that is single-layered, and has a thickness in a range from about 20 μm to about 60 μm.

Referring to FIG. 7J, the carrier 135 is removed, and the metal foil 133 is exposed.

Referring to FIG. 7K, the metal foil 133 is removed to expose the fourth surface 105b of the patterned insulating layer 105 and the second surface 101b of the patterned conductive layer 101. In this embodiment, the second surface 101b of the patterned conductive layer 101 is recessed above the fourth surface 105b of the patterned insulating layer 105. Recessing of the patterned conductive layer 101 can be carried out by any suitable technique. In this embodiment, partial removal of the patterned conductive layer 101 is carried out by etching.

Referring to FIG. 7L, an insulating material is disposed on the second surface 101b of the patterned conductive layer 101 and the fourth surface 105b of the patterned insulating layer 105, and is patterned to form the first protection layer 107. In this embodiment, the insulating material is disposed by inkjet printing, which allows precise control over areas to which the insulating material is disposed. The insulating material is patterned to have at least one first opening 107a. Then, a singulation process is performed. After that, a plurality of solder balls 119 can be attached to the second surface 101b of the patterned conductive layer 101 so as to form the semiconductor package 500 as illustrated in FIG. 5.

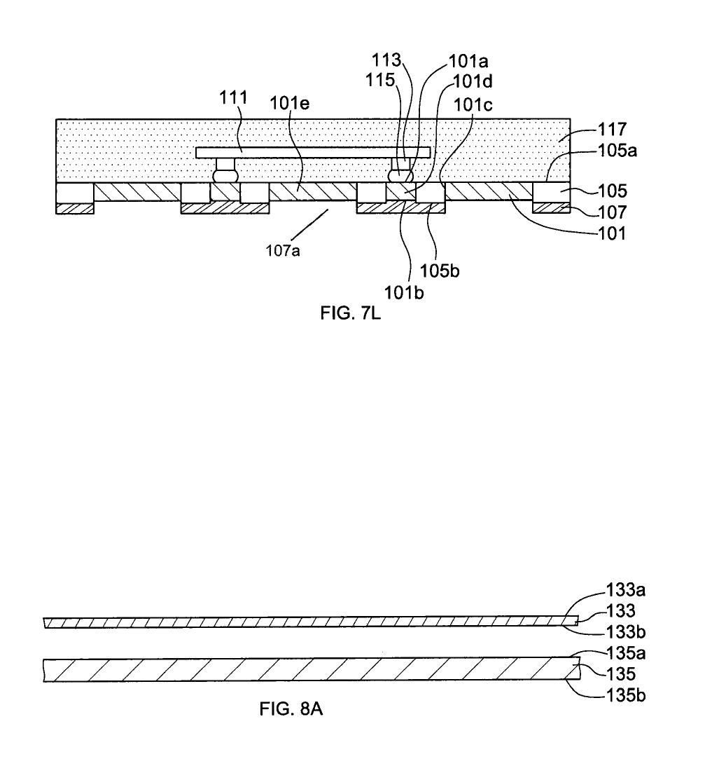

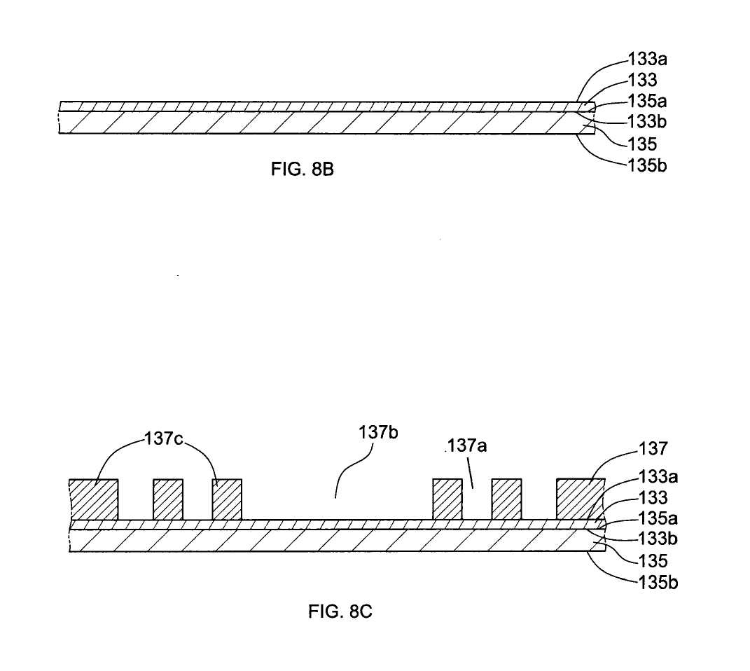

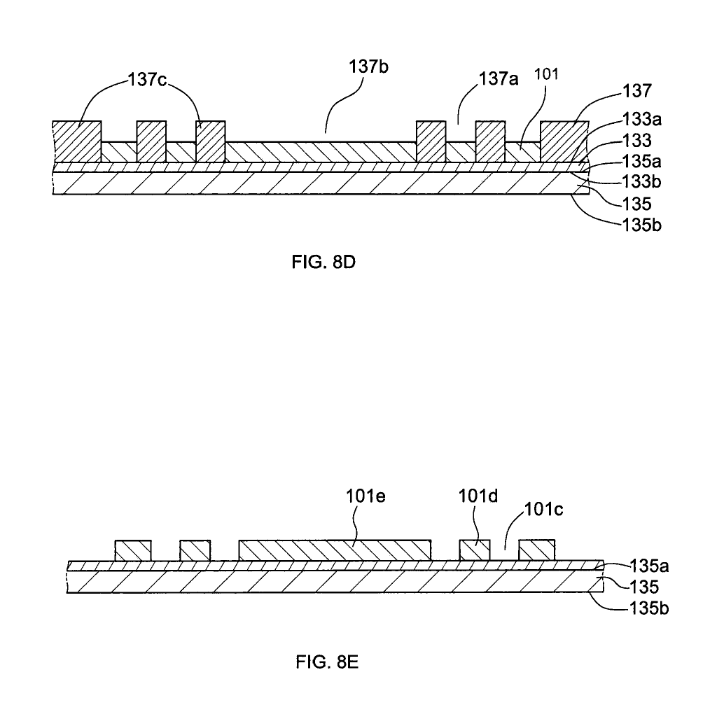

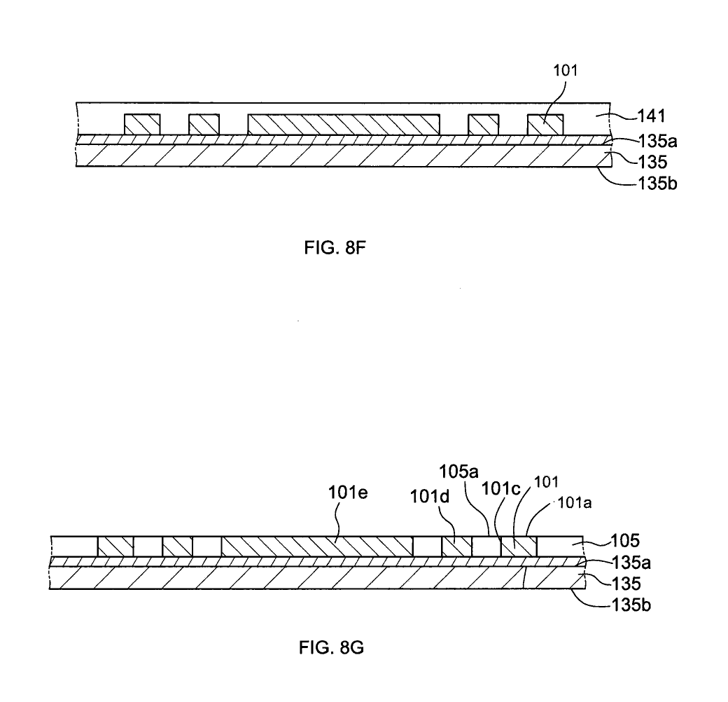

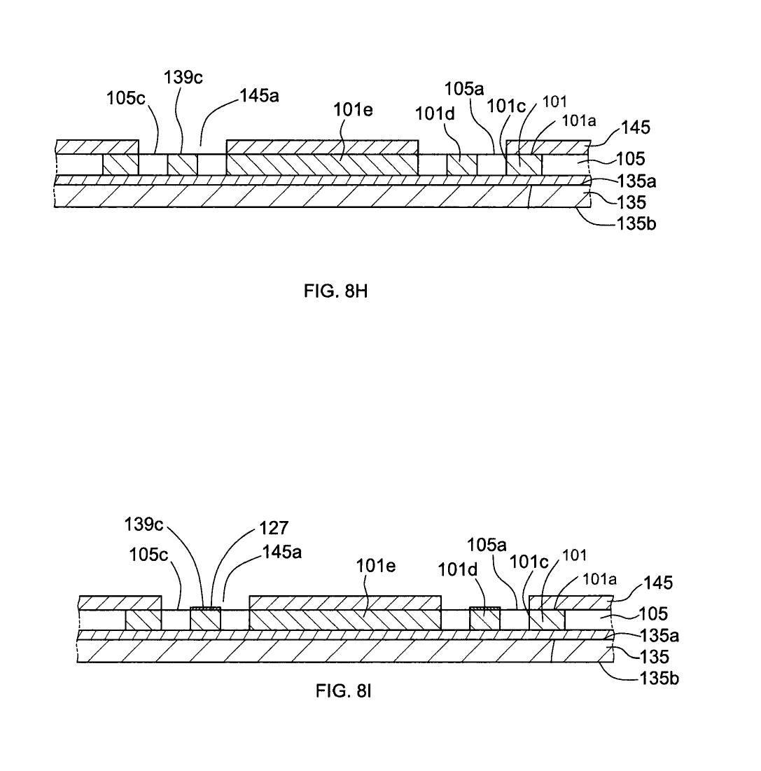

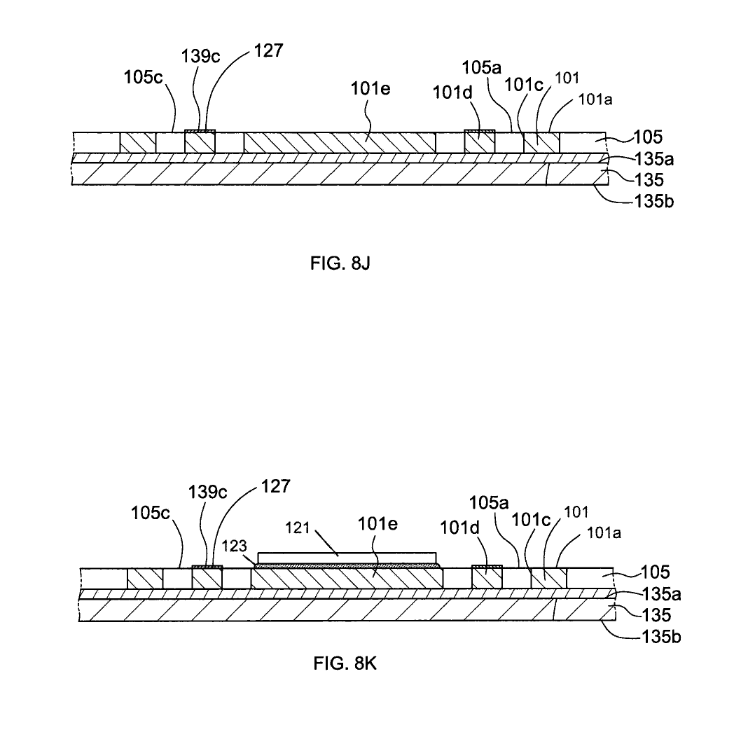

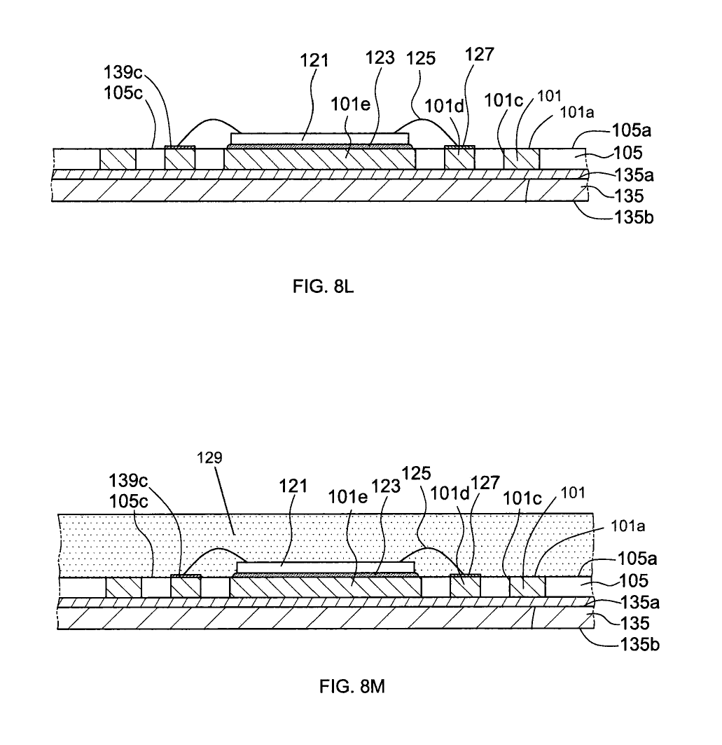

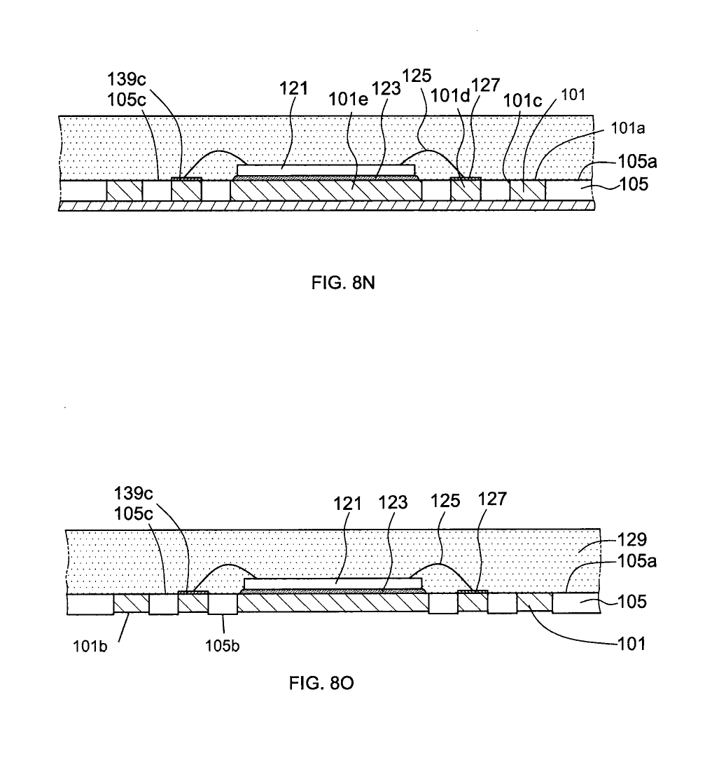

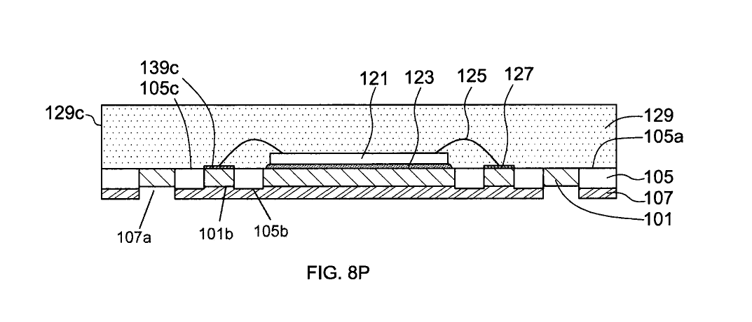

FIG. 8A, FIG. 8B, FIG. 8C, FIG. 8D, FIG. 8E, FIG. 8F, FIG. 8G, FIG. 8H, FIG. 8I, FIG. 8J, FIG. 8K, FIG. 8L, FIG. 8M, FIG. 8N, FIG. 8O, and FIG. 8P illustrate a process of manufacturing a semiconductor package according to another embodiment of the present disclosure.

The operations illustrated in FIG. 8A, FIG. 8B, FIG. 8C, FIG. 8D, FIG. 8E, FIG. 8F and FIG. 8G are similar to those described and illustrated with reference to FIG. 7A, FIG. 7B, FIG. 7C, FIG. 7D, FIG. 7E, FIG. 7F and FIG. 7G, respectively, and a discussion of these operations is not repeated below.

Referring to FIG. 8H, a patterned mask layer 145 is disposed on a portion of the first surface 101a of the patterned conductive layer 101 and a portion of the third surface 105a of the patterned insulating layer 105. A mask layer is patterned to form the patterned mask layer 145 to define a space to dispose the bonding pads 127. The patterned mask layer 145 has at least one opening 145a. The opening 145a exposes a portion 139c of the first surface 101a of the patterned conductive layer 101 and a portion 105c of the third surface 105a of the patterned insulating layer 105.

Referring to FIG. 8I, the bonding pads 127 are disposed on the exposed portion 139c of the first surface 101a of the patterned conductive layer 101. The bonding pads 127 can be formed by any suitable technique. In this embodiment, the bonding pads 127 are formed by electroplating or electroless plating.

Referring to FIG. 8J, the patterned mask layer 145 is removed.

Referring to FIG. 8K, the semiconductor element 121 is mounted to the first surface 101a of the patterned conductive layer 101. The semiconductor element 121 can be mounted to the first surface 101a of the patterned conductive layer 101 by any suitable technique. In this embodiment, the semiconductor element 121 is mounted to the first surface 101a of the patterned conductive layer 101 through the adhesive 123.

Referring to FIG. 8L, the semiconductor element 121 is electrically connected to the first surface 101a of the patterned conductive layer 101 by providing bonding wires 125 between the semiconductor element 121 and the bonding pads 127.

Referring to FIG. 8M, the encapsulant 129 (e.g., a molding compound) is disposed on the first surface 101a of the patterned conductive layer 101 and the third surface 105a of the patterned insulating layer 105. The encapsulant 129 covers the semiconductor element 121, the bonding wires 125, and the bonding pads 127.

Referring to FIG. 8N, the carrier 135 is removed.

Referring to FIG. 8O, after the carrier 135 is removed, the metal foil 133 is removed to expose the fourth surface 105b of the patterned insulating layer 105 and the second surface 101b of the patterned conductive layer 101. In this embodiment, the second surface 101b of the patterned conductive layer 101 is recessed above the fourth surface 105b of the patterned insulating layer 105. Recessing of the patterned conductive layer 101 can be carried out by any suitable technique. In this embodiment, partial removal of the patterned conductive layer 101 is carried out by etching.

Referring to FIG. 8P, an insulating material is disposed on the second surface 101b of the patterned conductive layer 101 and the fourth surface 105b of the patterned insulating layer 105, and patterned to form the first protection layer 107. The insulating material can be disposed by any suitable technique. In this embodiment, the insulating material is disposed by inkjet printing, which allows precise control over areas to which the insulating material is disposed. The insulating material is patterned to have at least one first opening 107a. Then, a singulation process is performed. After that, a plurality of solder balls 131 can be attached to the second surface 101b of the patterned conductive layer 101 so as to form the semiconductor package 600 as illustrated in FIG. 6.

As used herein and not otherwise defined, the terms “substantially” and “about” are used to describe and account for small variations. When used in conjunction with an event or circumstance, the terms can refer to instances in which the event or circumstance occurs precisely as well as instances in which the event or circumstance occurs to a close approximation. For example, the terms can refer to less than or equal to ±10%, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily be drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A semiconductor substrate, comprising:
a patterned conductive layer having a first surface and a second surface opposite the first surface, wherein the patterned conductive layer defines at least one space;
a patterned insulating layer disposed in the space and having a third surface and a fourth surface opposite the third surface, wherein the third surface of the patterned insulating layer does not protrude from the first surface of the patterned conductive layer, and the patterned insulating layer comprises, or is formed from, a cured photo-sensitive resin; and
a first protection layer covering at least a portion of the second surface of the patterned conductive layer.

2. The semiconductor substrate of claim 1, wherein the third surface of the patterned insulating layer is recessed below the first surface of the patterned conductive layer.

3. The semiconductor substrate of claim 2, wherein the third surface of the patterned insulating layer and the first surface of the patterned conductive layer are separated by a gap of about 3 μm to about 7 μm.

4. The semiconductor substrate of claim 1, wherein the patterned conductive layer comprises a plurality of traces and connection pads.

5. The semiconductor substrate of claim 1, further comprising a second protection layer disposed on the first surface of the patterned conductive layer and the third surface of the patterned insulating layer, wherein the second protection layer defines at least one opening to expose a portion of the first surface of the patterned conductive layer.

6. The semiconductor substrate of claim 1, wherein the patterned conductive layer has a thickness of about 14 μm to about 26 μm.

7. The semiconductor substrate of claim 1, wherein the second surface of the patterned conductive layer is recessed above the fourth surface of the patterned insulating layer.

8. A semiconductor package, comprising:
a semiconductor substrate, comprising:
a patterned conductive layer having a first surface and a second surface opposite the first surface, wherein the patterned conductive layer defines at least one space;
a patterned insulating layer disposed in the space and having a third surface and a fourth surface opposite the third surface, wherein the third surface of the patterned insulating does not protrude from the first surface of the patterned conductive layer, and the patterned insulating layer comprises, or is formed from, a cured photo-sensitive resin; and
a first protection layer covering at least a portion of the second surface of the patterned conductive layer;
a die disposed on the first surface of the patterned conductive layer; and
an encapsulant covering the die and the semiconductor substrate.

9. The semiconductor package of claim 8, wherein the third surface of the patterned insulating layer is recessed below the first surface of the patterned conductive layer.

10. The semiconductor package of claim 9, wherein the third surface of the patterned insulating layer has a concave profile, and a lowermost point of the third surface and the first surface of the patterned conductive layer are separated by a gap of about 3 μm to about 7 μm.

11. The semiconductor package of claim 8, wherein the third surface of the patterned insulating layer is substantially coplanar with the first surface of the patterned conductive layer.

12. The semiconductor package of claim 8, further comprising a second protection layer disposed on the first surface of the patterned conductive layer and the third surface of the patterned insulating layer, wherein the second protection layer defines at least one opening to expose a portion of the first surface of the patterned conductive layer.

13. The semiconductor package of claim 8, wherein the patterned conductive layer has a thickness of about 14 μm to 26 μm.

14. The semiconductor package of claim 8, wherein the second surface of the patterned conductive layer is recessed above the fourth surface of the patterned insulating layer.

15-20. (canceled)

21. A semiconductor substrate, comprising:
a patterned conductive layer defining at least one space;
an insulating layer disposed in the space, the insulating layer recessed from a first surface of the patterned conductive layer and protruding from a second surface of the patterned conductive layer; and
a protection layer covering a portion of the second surface of the patterned conductive layer.

22. The semiconductor substrate of claim 21, wherein the protection layer further covers the insulating layer protruding from the second surface of the patterned conductive layer.

23. The semiconductor substrate of claim 22, wherein the insulating layer and the protection layer comprise a same material and there is not a distinct boundary at an interface between the insulating layer and the protection layer.

24. The semiconductor substrate of claim 21, wherein the insulating layer recessed from the first surface of the patterned conductive layer has a concave profile, and a gap between the patterned conductive layer and a lowermost point of the concave profile is about 3 μm to about 7 μm.

25. The semiconductor substrate of claim 21, wherein the insulating layer comprises a cured photo-sensitive resin.

26. A semiconductor package, comprising:
a patterned conductive layer;
an insulating layer disposed in openings in the patterned conductive layer, the insulating layer recessed from a first surface of the patterned conductive layer and protruding from a second surface of the patterned conductive layer;
a die disposed over the first surface of the patterned conductive layer; and
an encapsulant covering the die and at least a portion of the first surface of the patterned conductive layer.
